(19) United States
(12) Patent Application Publication
(10) Pub. No.: US 2018/0054038 A1
(43) Pub. Date: Feb. 22, 2018

(54) SEMICONDUCTOR LASER APPARATUS

(71) Applicant: PHOVEL.CO.LTD., Daejeon (KR)

(72) Inventor: Jeong-Soo KIM, Sejong-si (KR)

(21) Appl. No.: 15/310,958

(22) PCT Filed: Jun. 24, 2016
(86) PCT No.: PCT/KR2016/006766

§ 371 Date: Nov. 14, 2016

(30) Foreign Application Priority Data
Jun. 23, 2016 (KR) 10-2016-0078869

(51) Int. Cl. H01S 5/026; H04B 10/50; H01S 5/20; H01S 5/22

(52) U.S. Cl. CPC H01S 5/0268; H04B 10/504; H04J 14/02; H01S 5/22; H04B 10/506; H01S 5/2018

(57) ABSTRACT

According to the present invention, in a time wavelength division multiplexing-passive optical network (TWDM-PON) such as the next generation passive optical network 2 (NG-PON2) requiring a burst mode operation, in a process of manufacturing a semiconductor laser requiring selection of a very narrow wavelength, two laser waveguides having different oscillation wavelengths are formed in one laser diode chip, thereby making it possible to improve a wavelength yield of the chip. In addition, when any one laser waveguide participates in communication, a current applied to a waveguide laser that does not participate in the communication is modulated and applied to the waveguide laser, with respect to a wavelength change generated by a change in a current applied to a burst mode operation waveguide laser participating in the communication, to stabilize a wavelength of laser light oscillated from the laser waveguide participating in the communication, thereby enabling burst mode communication at a dense wavelength division multiplexing (DWDM) level.

### TECHNICAL FIELD

The present invention relates to a semiconductor laser apparatus operated in a burst mode.

### BACKGROUND ART

A time wavelength division multiplexing (TWDM) scheme is a communication scheme standardized as a name “Next Generation Passive Optical Network 2 (NG-PON2)”. The TWDM scheme, which is a time division multiplexing (TDM) method in which a plurality of subscribers simultaneously connected to one optical fiber arbitrarily select any one of four or eight allowed wavelength channels and the plurality of subscribers using the same wavelength channels transmit and receive signals to and from one another in only a defined time, indicates a method of sharing an optical fiber.

An optical device performing communication in the TWDM scheme should have tunable characteristics of an oscillation wavelength so that it may arbitrarily select a wavelength channel. In addition, in the case in which another subscriber using the same wavelength channel band performs communication, the optical device performing communication in the TWDM scheme should not perform communication and should not oscillate laser light. In the case of using the time division multiplexing (TDM) method as described above, a burst mode operation in which a semiconductor laser is changed from a state in which it does not emit light into a state in which it suddenly emits the light may occur.

However, when a current flows to the semiconductor laser in the state in which the semiconductor laser does not emit the light, such that the semiconductor laser is changed into the state in which it emits the light, a temperature of an active layer of the semiconductor laser is changed. The change in the temperature of the active layer of the semiconductor laser generated depending on the change in the driving current of the semiconductor laser described above causes a change in an oscillation wavelength of the semiconductor laser.

Currently, an example of a semiconductor laser that may be currently used in an NG-PON2 scheme includes a distributed feedback laser diode (DFB-LD) chip. However, since the oscillation wavelength of the semiconductor laser is changed depending on the temperature of the active layer as described above, it is required to constantly maintain a temperature of a laser diode chip by a thermoelectric cooler in order to remove crosstalk between adjacent channels. Since the thermoelectric cooler very slowly reacts to the change in the temperature, it is impossible to make a wavelength constant by controlling the temperature of the active layer of the semiconductor laser when a burst starts using the thermoelectric cooler in a time wavelength division multiplexing-passive optical network (TWDM-PON) performing an ultra-high speed (G-bps (giga bit per second)) burst mode operation. However, the thermoelectric cooler may control a change in a wavelength by a change in an external environment in which the optical device is used.

The thermoelectric cooler is a device electrically controlling a temperature of devices disposed thereabove. The thermoelectric cooler may control a temperature of about 45° C. with respect to a temperature of the external environment. That is, when the temperature of the external environment is 85° C., a temperature that may be controlled using the thermoelectric cooler becomes at most about 40° C.

Currently, in the NG-PON2, channels are set at a frequency interval of 100 GHz (approximately 0.8 nm in a wavelength band of 1532 nm). In the case of using a general 11 GHz/° C. DFB-LD chip among the DFB-LD chips as a light source, a frequency may be changed into an adjacent channel when a temperature of approximately 9° C. is controlled. For example, in the case in which a wavelength of a first channel is obtained at 40° C., a wavelength of a second channel is obtained at 49° C., a wavelength of a third channel is obtained at 58° C., and a wavelength of a fourth channel is obtained at 67° C. In the case in which the wavelength of the first channel is obtained at 50° C., the wavelength of the second channel is obtained at 59° C., the wavelength of the third channel is obtained at 68° C., and the wavelength of the fourth channel is obtained at 77° C. Since a reaction speed of the DFB-LD chip is decreased at a high temperature, it is preferable to drive the DFB-LD chip at a temperature as low as possible. In addition, in the case of continuously driving the DFB-LD chip at an excessive high temperature, a problem occurs in reliability. Therefore, it is preferable that a driving temperature of the DFB-LD chip is as low as possible. However, it is preferable that the thermoelectric cooler sets a channel at 40° C. or more in terms of temperature control of the thermoelectric cooler when considering a case in which the temperature of the external environment is changed.

When considering these contents, it is preferable that a temperature of the first channel of the DFB-LD chip is set between 40 to 50° C.

The setting of the channels of the DFB-LD chip is determined by the chip of the DFB-LD chip. Generally, the DFB-LD chip is manufactured by a method of forming grating periods in a semiconductor active layer, and the method of manufacturing the DFB-LD chip described above includes a process of a semiconductor wafer having a diameter of two inches or three inches. In the manufacturing of the DFB-LD chip performed through the process of the semiconductor, wavelength precision and uniformity of the DFB-LD chip generally show reproducibility of +/−5 nm. In order to dispose a temperature of the first channel in a section of 10° C., a wavelength of the DFB-LD chip should be in about +/−0.4 nm at a temperature of 45° C. In order to dispose the temperature of the first channel in a section of 40° C. to 50° C. as compared with a wavelength distribution +/−5 nm obtained in the general process of manufacturing the DFB-LD chip, only a specific wavelength should be selected in a wide wavelength distribution appearing in the manufacturing of the DFB-LD chip. This decreases a manufacturing yield of the DFB-LD chip to increase a cost of the laser DFB-LD chip used in the NG-PON2.

### DISCLOSURE

### Technical Problem

The present invention has been suggested in order to solve the problems in the related art, and an object of the present invention is to provide a method for increasing a wavelength selection yield of a distributed feedback laser diode (DFB-LD) chip and minimizing a wavelength change depending on turn-on/off of a laser in the DFB-LD chip operated in a burst mode.

### Technical Solution

In the present invention for accomplishing the above-mentioned object, two (A and B) laser waveguides spaced apart from each other by a predetermined distance are formed in one laser diode chip, and gratings having different periods are buried in the respective laser waveguides so that wavelengths of laser light oscillated from the respective laser waveguides have a predetermined wavelength difference therebetween. In the case of generating laser light used for communication using the A laser waveguide, the B laser waveguide is turned off when the A laser waveguide is turned on, and the B laser waveguide is turned on when the A laser waveguide is turned off, thereby offsetting a temperature fall in an active region of the A laser waveguide by heat generated in the B laser waveguide. As described above, a temperature of the A laser waveguide used for the communication is always constantly maintained regardless of the turn-on/off of the A laser waveguide, such that the laser light oscillated from the A laser waveguide may have a constant wavelength regardless of the turn-on/off of the A laser waveguide, and turn-on/off of a laser waveguide of one channel does not cross-talk to a wavelength band of another channel in a time wavelength division multiplexing-passive optical network (TWDM-PON) such as the NG-PON2, or the like, in which several wavelengths are used, thereby making it possible to perform smooth communication.

### Advantageous Effects

As described above, according to the present invention, two laser waveguides having different grating periods are used in one semiconductor laser diode chip, thereby making it possible to improve a wavelength yield of the chip. In addition, according to the present invention, the two laser waveguides are alternately turned on/off to stabilize wavelengths of laser light participating in optical communication regardless of turn-on/off of a laser waveguide participating in the optical communication, thereby making it possible to perform smooth optical communication.

### DESCRIPTION OF DRAWINGS

FIG. 1 is a view for describing a structure of a distributed feedback laser diode (DFB-LD) chip according to the related art.

FIG. 2 is a conceptual diagram of a DFB-LD chip having a dual active waveguide structure according to the related art.

FIG. 3 is a conceptual diagram of a DFB-LD chip having a dual active waveguide structure according to an exemplary embodiment of the present invention.

FIG. 4 is a conceptual diagram of a laser diode chip to which an electrical heater is added.

FIG. 5 is a view for describing a method of driving a DFB-LD chip having a dual active waveguide structure according to an exemplary embodiment of the present invention.

FIG. 6 is a view illustrating a temperature change in a B-waveguide in the case in which a current of 80 mA flows to an A-waveguide.

FIG. 7 is a view illustrating a ratio in which light emitted from the A-waveguide is coupled to an optical fiber depending on a distance between the A-waveguide and the B-waveguide.

### DETAILED DESCRIPTION OF THE PREFERRED EMBODIMENT

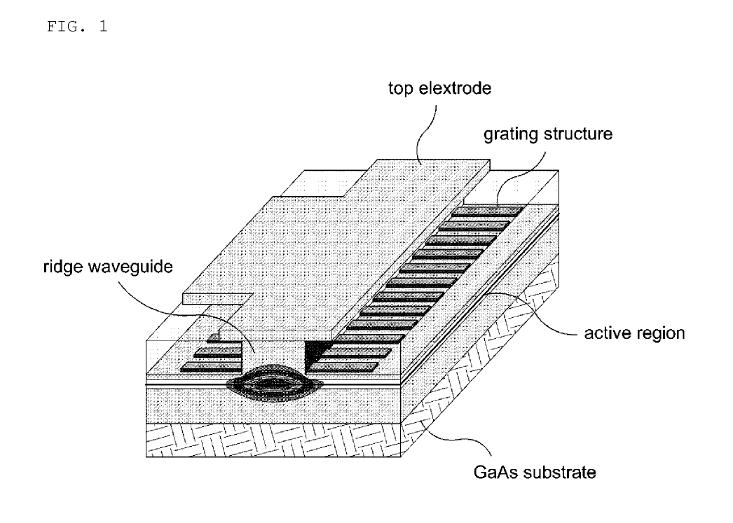

FIG. 1 is a view for describing a structure of a distributed feedback laser diode (DFB-LD) chip according to the related art.

Referring to FIG. 1, the DFB-LD chip is configured by forming gratings having high and low refractive indices in a laser active region formed in a waveguide structure. A wavelength of the DFB-LD chip is determined by a period of the grating, an effective refractive index of the active region, and the like. The effective refractive index of the active region is determined by several factors such as a thickness of an active layer, a width of the waveguide, and the like. Since it is significantly difficult to very precisely control the effective refractive index of the active region, a case in which the wavelength of the DFB-LD chip is changed depending on positions even in a wafer manufactured by the same process according to reproducibility and uniformity in a semiconductor wafer process frequently occurs. Therefore, run-by-run reproducibility of the wafer process is significantly bad, such that it has been known that the wavelength of the DFB-LD chip has uniformity and reproducibility of +/−3 nm even in a process generally managed well.

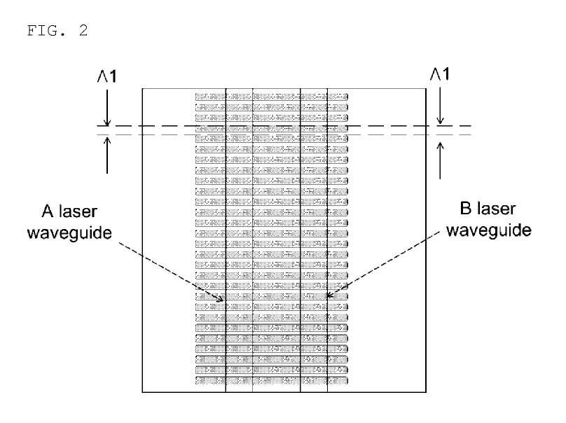

FIG. 2 is a conceptual diagram of a DFB-LD chip having a dual active waveguide structure according to the related art.

Referring to FIG. 2, two independent laser waveguides according to the related art are configured to be operated by independent lasers on gratings having the same grating period of Λ1. The purpose of the dual active waveguide structure described above is to increase a yield of a laser chip by using the other of the two laser waveguides in the case in which any one of the two laser waveguides is not operated. Application of the DFB-LD chip according to the related art allows a wavelength deviation of +/−3 nm, such that a yield of the chip depending on a wavelength is not problematic. Therefore, the two waveguides of FIG. 2 have the same grating period and the same grating structure, and a yield according to whether or not a laser diode chip is operated except for wavelength specifications of the laser diode chip may be increased by forming only the two waveguides.

Currently, in the case of a channel having a wavelength interval of 100 GHz (a wavelength interval of approximately 0.8 nm in a band of 1532 nm) such as the next generation passive optical network 2 (NG-PON2), as described above, a temperature of a first channel should be set in a section between 40° C. to 50° C. This means that a DFB-LD chip having a wavelength in a range of approximately +/−0.5 nm of a wavelength of the first channel on the basis of 45° C. should be selected. The selection of the chip in the narrow wavelength region described above significantly decreases a wavelength yield of the chip. Since the two laser waveguides formed on the basis of the same gratings according to the related art generate the same wavelength, even though the laser chip having the dual active waveguide structure is manufactured in a scheme according to the related art, a yield depending on the wavelength of the chip may not be increased.

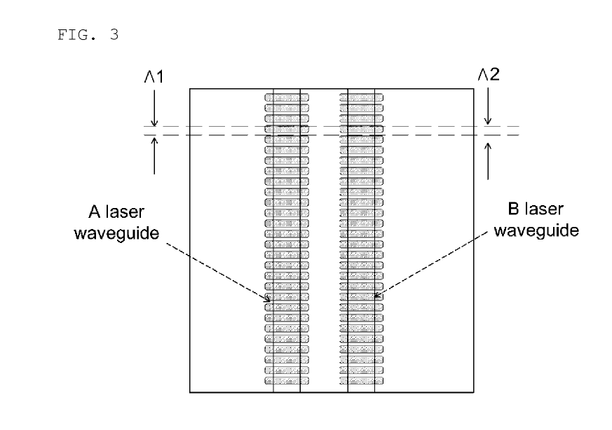

FIG. 3 is a conceptual diagram of a DFB-LD chip having a dual active waveguide structure according to an exemplary embodiment of the present invention.

Referring to FIG. 3, in a dual active waveguide laser according to an exemplary embodiment of the present invention, the respective laser waveguides are independently implemented on gratings having different grating periods Λ1 and Λ2. As a method for forming gratings so as to have different grating periods in a narrow region, there is an e-beam lithography method.

Therefore, in one chip, gratings in a predetermined region are formed to have a grating period of Λ1, gratings in another region are formed to have a grating period of Λ2, such that independent laser waveguides are formed in the regions corresponding to the grating periods Λ1 and Λ2, respectively. Here, the grating period Λ1 and the grating period Λ2 may have a difference therebetween so as to have a predetermined wavelength difference therebetween. When it is assumed that a wavelength difference by a grating period difference between two independent laser diode chips is Δλ and a wavelength by a first laser waveguide is λ1, a second laser waveguide has a wavelength of λ1+Δλ. In the case in which Δλ is larger than 1 nm, the respective waveguides may have a wavelength in a range of +/−0.5 nm. In terms of a selection rule, since the chip have two independent laser diode chips, when any one of λ1 and λ2 is present in a desired wavelength band, the chip may be used, such that a wavelength selection yield of the chip may be increased doubly.

Since Δλ is not precisely controlled in a process of actually manufacturing the chip, it is preferable to select Δλ in consideration of this uncertainty. For example, Δλ has a value of, preferably, 0.5 to 3 nm, more preferably, 0.5 to 2 nm.

Currently, a wavelength interval of an allowable channel of the NG-PON2 is about 100 GHz (˜0.8 nm), and when considering a region required for wavelength separation, a wavelength of the laser should be controlled in +/−20 GHz(·+/−0.16 nm) from a given wavelength. However, in the case in which the laser diode chip is operated in a burst mode, the laser is changed from a turn-off state in which a current is not applied thereto into a turn-on state in which a current is applied thereto to provide signals “1” and “0”. When the laser is changed from the state in which the current does not flow into the state in which the current flows, Joule heat is generated in the laser waveguide. Therefore, a temperature of a laser active is changed, and the wavelength is changed. The wavelength by the Joule heat in the laser active is continuously changed from a microsecond (μsec) to several tens of milliseconds (msec). Wolfgang Poehlmann (J. of Optical Communications and Networking (Volume: 7, Issue: 1) p 44, 2015) has reported a wavelength change up to 60 GHz at 50° C. A wavelength change in msec depending on the turn-on/off of the laser diode chip may not be controlled using a thermoelectric cooler having a slow reaction speed. This wavelength change may be suppressed by additionally attaching an electrical heater to the laser diode chip and alternately operating the electrical heater and the laser diode chip.

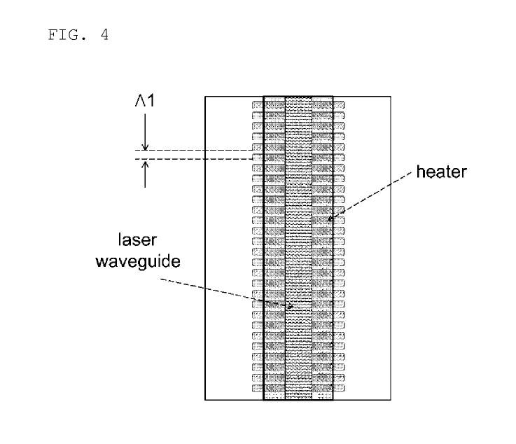

FIG. 4 is a conceptual diagram of a laser diode chip to which an electrical heater is added.

Referring to FIG. 4, in order to compensate for the wavelength change depending on the turn-on/off of the laser diode chip, the electrical heater may be driven to offset a short wavelength change in msec. However, in this structure, the number of laser waveguide is one, such that a wavelength selection yield is decreased.

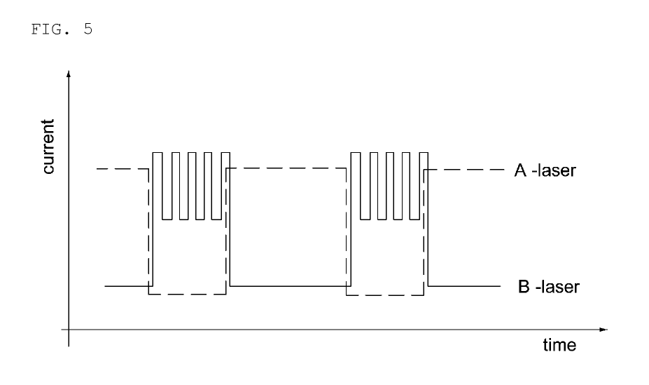

FIG. 5 is a view for describing a method of driving a DFB-LD chip having a dual active waveguide structure according to an exemplary embodiment of the present invention.

Referring to FIG. 5, in the present invention, grating portions having different grating periods Λ1 and Λ2 are formed in one laser diode chip, and independent laser waveguides are formed in the respective grating portions. A method for using the other waveguide of which an emission wavelength is not selected as a heater when an emission wavelength of any one of the laser waveguides is selected is suggested. For example, in the case in which a B laser waveguide is selected as a laser waveguide directly applied to communication as illustrated in FIG. 5, the B laser waveguide is operated as a laser in a general burst mode. That is, in the case in which the communication is not performed, a current flowing to the B laser waveguide is maintained at a value lower than a threshold current of the laser diode chip. On the other hand, in the case in which the communication starts, currents corresponding to a signal “1” and a signal “0” are applied to the B laser waveguide.

When the B laser waveguide is in a turn-off state, a predetermined relatively large current is applied to an A laser waveguide.

To the contrary, when the B laser waveguide is in a turn-on state, a predetermined small current is applied to the A laser waveguide.

When the current alternately flows to the waveguides of the two laser diode chips in this scheme, when the B laser waveguide participating in the communication is in the turn-off state, Joule heat may be generated by the current flowing to the A laser waveguide.

To the contrary, when the B laser waveguide is in the turn-on state, the current flowing to the A laser waveguide is blocked. Therefore, a temperature of the B laser waveguide may be constantly maintained regardless of whether or not the B laser waveguide participating in the communication is operated.

A magnitude of the current flowing to the A laser waveguide that does not participate in the communication may be predetermined to be a numerical value making a temperature of the B laser waveguide constant.

Since the A laser waveguide is not used for the communication, a magnitude of the current flowing to the B laser waveguide may be controlled in three steps such as “turn-off”, “1”, and “0”, while a magnitude of the current flowing to the A laser waveguide may be controlled in two steps such as a low current state and a high current state. When the A laser waveguide that does not participate in the communication is in the high current state, it is preferable that this current is not modulated. The reason is that in the case in which laser light oscillated from the A laser waveguide participates in the communication, a direct current (DC) component of the laser light that is not modulated does not disturb the communication.

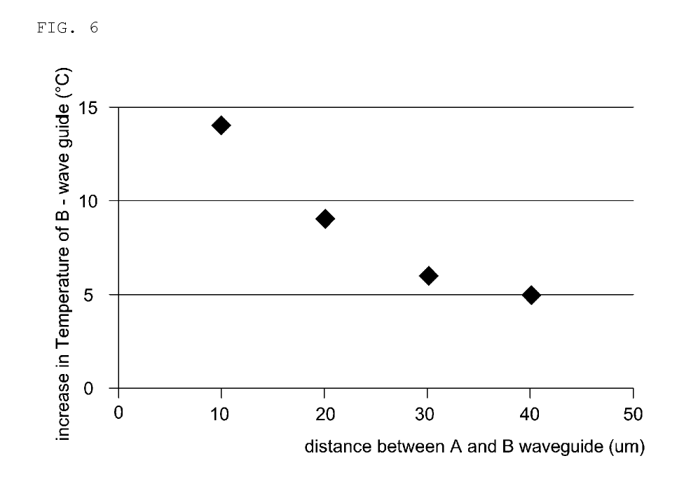

FIG. 6 is a view illustrating a temperature change in a B-waveguide in the case in which a current of 80 mA flows to an A-waveguide.

Referring to FIG. 6, since two adjacent laser waveguides are spaced apart from each other in terms of a position, an influence of a current used in the A-waveguide on a temperature of the B-waveguide is changed depending on a distance between the A-waveguide and the B-waveguide. As the distance between the A-waveguide and the B-waveguide becomes long, contribution of the A-waveguide to the temperature of the B-waveguide is decreased. In order to decrease current consumption, it is advantageous that a current consumption amount of the A-waveguide is small for constantly maintaining the temperature of the B-waveguide. To this end, it is advantageous that a distance between the A-waveguide and the B-waveguide is as short as possible. However, in the case in which the distance between the A-waveguide and the B-waveguide is excessively short, there is a problem that light generated in the A-waveguide operated in order to maintain the temperature may be transmitted when the B-waveguide participating in the communication is in a turn-off state. Therefore, it is preferable that the distance between the A-waveguide and the B-waveguide is wide in order for laser light generated in the A-waveguide not to participate in transmission.

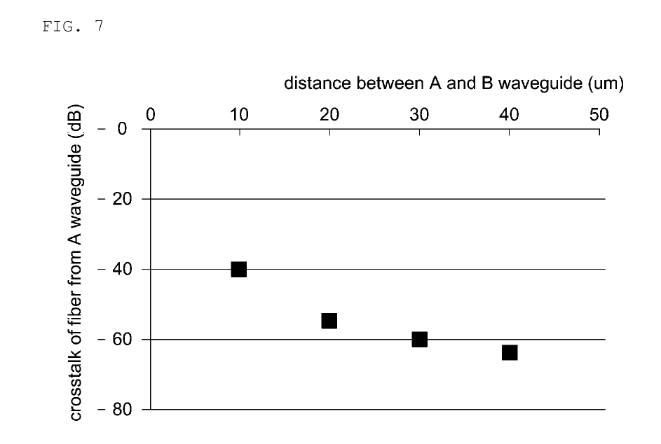

FIG. 7 is a view illustrating a ratio in which light emitted from the A-waveguide is coupled to an optical fiber depending on a distance between the A-waveguide and the B-waveguide.

Referring to FIG. 7, as the A-waveguide and the B-waveguide become close to each other, a crosstalk ratio between light emitted from the A-waveguide that does not participate in the communication and the communication is −40 dB. Therefore, it is predicted that crosstalk becomes large in the case in which the distance between the A-waveguide and the B-waveguide becomes short.

On the other hand, in the case in which the distance between the A-waveguide and the B-waveguide is larger than 30 μm, a decrease effect of the crosstalk depending on the distance is saturated.

Therefore, when considering the influence of the current on the temperature of the waveguide of FIG. 6 and the crosstalk of FIG. 7, it is appropriate that the distance between the A-waveguide and the B-waveguide is about 10 to 30 μm.

Although a case in which the number of waveguides is two has been described by way of example in an exemplary embodiment of the present invention, the number of waveguides may also be three or more.

Various modifications and alterations may be easily made by those skilled in the art to which the present invention pertains without departing from essential features of the present invention, using the exemplary embodiments of the present invention described above. Contents in each of the claims may be combined with other claims that are not cited in a range that may be understood through the present specification.

1. A semiconductor laser apparatus including two or more laser waveguides independently operated in one semiconductor laser diode chip,
wherein the two or more laser waveguides are formed on gratings having different periods, respectively.

2. The semiconductor laser apparatus of claim 1, wherein a current flowing to any one of the other laser waveguides that do not participate in communication is modulated and applied to any one of the other laser waveguides in order to offset a temperature change generated when any one laser waveguide that participates in the communication, of the two or more laser waveguides, is turned on and turned off.

3. The semiconductor laser apparatus of claim 2, wherein when a three-step current including a current corresponding to “turn-off”, a current corresponding to a signal “1”, and a current corresponding to a signal “0” flows to any one laser waveguide that participates in the communication, a two-step current including a “low” current and a “high” current flows to any one of the other laser waveguides that do not participate in the communication.

4. The semiconductor laser apparatus of claim 2, wherein wavelengths of laser light oscillated from the two or more laser waveguides have a difference of 0.5 nm to 2 nm therebetween.

5. The semiconductor laser apparatus of claim 2, wherein the two or more laser waveguides are spaced apart from each other by 10 μm to 30 μm.
